(19) United States
(12) Patent Application Publication
(10) Pub. No.: US 2012/0234366 A1
(43) Pub. Date: Sep. 20, 2012

(54) METHOD FOR THE PRODUCTION AND SERIES CONNECTION OF PHOTOVOLTAIC ELEMENTS TO GIVE A SOLAR MODULE AND SOLAR MODULE

(76) Inventors: Andreas Lambertz, Juelich (DE); Stefan Haas, Baesweiler (DE)

(21) Appl. No.: 13/138,963

(22) PCT Filed: Apr. 21, 2010
(86) PCT No.: PCT/DE2010/000447

§ 371 Date: Dec. 6, 2011

(30) Foreign Application Priority Data
May 8, 2009 (DE) 10 2009 020 482.2

(51) Int. Cl. H01L 31/18; H01L 31/02

(52) U.S. Cl. 136/244; 438/80; 438/69; 257/E31.113; 257/E31.127

(57) ABSTRACT

Disclosed is a method for producing and for connecting in series photovoltaic elements to form a solar module, and a solar module.

The invention relates to a method for producing and for connecting in series photovoltaic elements to form a solar module, and to a solar module.

### PRIOR ART

The series connection of photovoltaic elements to form a solar module is used to combine light-induced energy that is generated in the elements, without generating a short circuit therein. To this end, a first electrical contact is conductively connected to a second electrical contact in two photovoltaic elements, wherein the contacts, which are also referred to as electrodes, are disposed on opposing sides of the active semiconductor layers.

It is known from the prior art to apply a first electrical contact over the entire surface area of a substrate. Thereafter, this contact is divided, starting from the surface and reaching down into the substrate, into several parallel stripes by way of a first structuring step. Following the first structuring process, active semiconductor layers having a p-i-n or p-i-n-p-i-n structure are applied to the entire surface area of the surface of the structured first contact, whereby the trenches located therein are filled in. In a second structuring process, the semiconductor layers are divided, starting from the surfaces thereof and up to the surface of the first electrical contact, into several stripes. This second structuring process, and thus the subdivision of the semiconductor layers, takes place as close as possible next to and parallel to the first structuring process and the trenches of the first electrical contact. Thereafter, a second electrical contact is provided on the surface of the photovoltaic element that has been divided into stripes, and is in turn divided into stripes, on the first electrical contact that has been thus structured and the semiconductor stripes extending parallel thereto. In a third structuring process, the second electrical contact, starting from the surface thereof and up to the surface of the semiconductor layers, is divided into several stripes. This third structuring process takes place as close as possible next to and parallel to the second structuring process and parallel to, but further spaced apart from the first structuring process.

The disadvantage of this method is that the vacuum process for depositing the individual contacts and the photovoltaic element must be interrupted by the structuring processes. It is further disadvantageous that the entire module has to be adjusted and realigned prior to each structuring process. In practice, this results in interconnection losses due to the structuring processes and subdivisions. The temperature fluctuations during the structuring processes must be small. Parasitic shunt resistances occur as a result of the doped layers that are applied to the first electrical contact. If highly conductive intermediate layers are provided, short circuits of the individual cells may occur due to the second electrical contact.

Moreover, the method known from the prior art has disadvantages in terms of the usage of electrically conductive layers in the region between the p-i-n structures, because these electrically conductive layers, in combination with the method known from the prior art, can electrically short-circuit the second p-i-n structure.

Another method for connecting photovoltaic elements in series to form solar modules is known from WO 2008/074879 A2. According to this method, a first electrical contact, or a first electrode, is first deposited over the entire surface area of a substrate, and then the active semiconductor layers for the solar cell are deposited thereon, again over the entire surface area. Thereafter, two structuring processes are carried out consecutively, during which the trenches are formed close to each other, but not directly adjacent to each other. A first trench is provided down to the surface of the substrate, and the second trench is provided parallel to the first trench up to the surface of the first electrical contact. The first trench extending to the surface of the substrate is then roughly filled with an insulating compound such that the second trench is not affected. Then, a lift-off compound is deposited onto the surface of the photovoltaic element parallel to the first and second trenches. The lift-off compound is located further from the insulating compound than from the second trench. The material for the second electrical contact, or the second electrode, is then deposited over the entire surface area of the layer structure thus formed, the second trench is filled in, and the insulating compound and the lift-off compound are covered. After locally removing the second electrical contact above the lift-off compound, a trench is formed in the second electrical contact up to the surface of the active semiconductor material, whereby the series connection is established.

The disadvantage is that this method is not suitable for an industrial series connection of the individual solar modules. The filling process using an insulating compound and a lift-off compound, and the resulting method, prevent the desired high throughput when forming the interconnects and series connection.

Another method for structuring and for connecting photovoltaic elements in series to form thin-film solar modules is known from WO 2007/044555 A2. According to this method, a stack of active and conducting layers are provided consecutively over the entire surface area of a substrate in a single deposition process so as to form the solar cell. Thereafter, the structuring processes are carried out consecutively, whereby the interconnects for the series connection of the individual solar modules are produced. This advantageously eliminates various adjustments following the individual deposition processes. According to the method, two consecutive structuring processes are carried out after depositing the second electrical contact. A first structuring is produced from the surface of the second electrical contact down to the glass substrate, and a second, further structuring is produced, which is directly next to and parallel to the first structuring, extending up to the surface of the first electrical contact. After the substrate and the first electrical contact are exposed, a conducting shoulder or a ledge is formed, which is filled with an insulator from the surface of the second electrical contact down to the substrate. The exposed ledge or shoulder, and thus the surface of the first electrical contact, as well as a portion of the substrate remain unaffected by this. Then, so as to form the interconnect, the connection from the surface of the first electrical contact to the surface of the second electrical contact is established on this insulator, using a conductive material. This method is described in FIG. 6 et seq. The disadvantage is again that this method is not suitable for industrial series connection of the individual photovoltaic elements.

### Problem and Solution

It is the object of the invention to provide a method for generating, and for connecting in series, photovoltaic elements to form solar modules, which is easier to implement and achieves higher throughput than is known from the prior art.

The object is achieved by a method according to claim 1. Advantageous embodiments will be apparent from the dependent claims.

A first electrical contact layer is provided on a substrate. Substrates or superstrates, which are customary, for example, in (thin-film) solar cell technology, are employed as the substrate. These include metal foils made of steel or aluminum (substrate), plastic films made of PEN, or the glass substrates provided for in superstrate technology, comprising or not comprising non-conductive intermediate layers on the surface.

Possible materials for the first electrical contact layer include in particular materials such as the silver/ZnO layers used in substrate technology and ZnO, SnO₂ or ITO layers used in superstrate technology.

In a second step, active semiconductor layers, and more particularly p-i-n or p-i-n-p-i-n or corresponding n-i-p structures, are provided on top of each other over the entire surface area of the first electrical contact layer.

The p-i-n structure used is, for example, a structure comprising amorphous silicon. A possible p-i-n-p-i-n structure is, for example, a structure comprising amorphous silicon and microcrystalline silicon.

In a further step, a second electrical contact layer is provided on the active semiconductor layers on the side of the semiconductor layers that is opposite of the first contact layer. This results in a layer structure, comprising a substrate/superstrate, comprising or not comprising a non-conductive intermediate layer, a first electrical contact layer provided thereon, a semiconductor structure provided thereon and a second electrical contact layer provided thereon.

A PECVD method, or sputtering method, or photo CVD or HWCVD or comparable method may be employed for deposition.

Thereafter, a number of parallel stepped trenches are generated so as to form and separate a corresponding number of stripe-shaped photovoltaic elements (A, B, C . . . ). The stepped trenches can optionally be created in a single step, or in two steps, by suitably selecting lasers having various wavelengths and as a function of the materials to be removed. In the stepped trenches, the surface of the substrate/superstrate and the surface of the first contact layer are exposed next to one another in step form.

The stepped trenches are produced as follows: In the stepped trenches, the surface of the substrate is exposed over the length of the photovoltaic elements, for example in a stripe shape. Instead of a stripe shape, a meander shape or another shape may be selected when removing layers over the length of the elements.

As with the substrate surface, the surface of the first electrical contact layer next to the exposed substrate surface can be exposed, for example in a stripe shape over the entire length of the photovoltaic elements or, as seen over the length of the photovoltaic elements, can be locally exposed in some regions. To this end, the semiconductor layers and the second electrical contact layer are removed, whereby the stepped trenches are created. The semiconductor layers and the second electrical contact layer can be removed consecutively, for example in the form of points, at certain distances. In the latter case, the surface of the first electrical contact layer will be exposed only in some regions, which is to say at certain points above the substrate.

It is conceivable for the exposed substrate surface and the exposed first electrical contact layer not to be exposed directly adjacent to one another in the stepped trenches. Narrow ridges will then remain between them.

The stepped trenches disposed parallel to one another divide the layer structure into a corresponding number of, for example stripe-shaped, photovoltaic elements that are disposed parallel to one another. Each photovoltaic element comprises a layer sequence that is composed of a substrate/superstrate, optionally an intermediate layer, a first electrical contact layer, active semiconductor layers, and a second electrical contact layer. The photovoltaic elements are present parallel next to one another in accordance with the structurings.

According to the method, insulator material is then provided at least in the stepped trenches. The insulator can be applied in a stripe-form or punctiform manner, for example, by way of spraying using an appropriately arranged mask, or preferably by way of an ink jet printer comprising or not comprising a mask. The printer is preferably computer-controlled. Conventional ink jet printing ink may be used.

The advantage of this structuring is that the insulator does not have to be disposed with particular precision in the stepped trenches. Rather, the insulator can be provided laterally over the flanks of the stepped trenches up to the surface regions of the second electrical contact layer that laterally adjoin the stepped trenches. Moreover, the insulator does not have to completely fill the stepped trench. It suffices that the surfaces of the layers in the stepped trenches are covered by a thin layer.

The insulator has at least the lateral extension of the stepped trench. It is provided in the stepped trench, so that the exposed surfaces of the substrate and of the first electrical contact layer are covered by the insulator. The insulator may cover the surface of the second electrical contact layer on both sides along the trenches laterally beyond the two flanks of the stepped trench. This advantageously achieves considerable time savings in comparison with the prior art. The insulator can be applied using photolithography by means of a mask technology. In one embodiment of the invention, the insulator may also be applied to the entire surface areas of the layers and stepped trenches.

For the series connection, the insulator is once again locally removed in the stepped trenches, so that the surface of the first electrical contact layer, and optionally also that of the substrate/superstrate in the second stepped trenches is exposed in the resulting cut-outs. The semiconductor layers and the second contact layer are not exposed. It suffices to expose the surface of the first electrical contact layer by removing the insulator. In the event that the surface of the substrate/superstrate is also exposed, a second stepped trench is formed. Thus, for two mutually adjoining photovoltaic elements, only the first contact layer of one of the two adjoining elements is exposed. The insulator can be removed in a stripe-shaped manner over the entire length of the photovoltaic elements or regions, which is to say locally. The surface of the first electrical contact layer of a particular photovoltaic element which is exposed in the trenches, and optionally the surface of the substrate/superstrate, are then electrically connected in series with the second electrical contact layer of the adjoining photovoltaic element, without creating short circuits.

For this purpose, contact material is provided from the surface of the second electrical contact layer of a photovoltaic element to the surface of the first electrical contact layer of the adjoining photovoltaic element from which the insulator material has been removed, so that the two adjoining photovoltaic elements are connected in series to one another. This process is repeated for all photovoltaic elements. The contact material that is applied is an electrically conductive material such as silver, and is preferably applied by means of ink jet printing or screen printing.

The method allows punctiform or stripe-shaped regions of insulator material and/or contact material to be formed, which extend over the length of the photovoltaic elements.

The step, according to which the insulator is provided in the stepped trenches, and the step, according to which the contact material for the series connection of adjoining photovoltaic elements is provided from the surface of the second electrical contact layer of a photovoltaic element to the surface of the first electrical contact layer of an adjoining photovoltaic element, particularly advantageously allow the method to be carried out considerably more quickly than according to the prior art.

This is because, in comparison with the prior art, the insulator material and the contact material can be provided laterally in the stepped trenches and, over the two lateral flanks of the trenches, up to the surface of the second electrical contact layer, with comparatively less precision. It is not necessary for the insulator, or the contact material, to completely fill in the trenches. It is also not necessary to provide the insulator material and the contact material only in portions of the trench, as is known from the prior art. Instead, it should be ensured that the exposed surface of the first electrical contact layer, and the optionally exposed substrate surface at the base of the trench, as well as the surfaces of the layer system which have been exposed at the two flanks of the trench, are covered. Electrical short circuiting of the element is thus prevented.

Depending on the method, a stepped trench can, for example, have lateral dimensions of 10 to 100, and more preferably of 50 to 100 μm, for example. The insulator stripe and the insulator points or regions can have larger lateral dimensions or diameters, for example up to several millimeters. The same applies to the contact material.

In the form of a stripe, the insulator can have lateral dimensions of up to 5 mm. The same applies to the contact material, which subsequent to exposure of the first electrical contact layer is provided on the layer structure for the series connection.

The insulator material and the contact material can be provided in the stepped trench, and optionally on the second electrical contact layer, in a width that is greater than the stepped trench by a factor of 1 to 100, for example.

Advantageously, by depositing all layers consecutively without structuring the same, which is to say the substrate/superstrate, first electrical contact layer, active semiconductor layers and second electrical contact layer, the method can be considerably expedited. Further time saving takes place subsequent to structuring when applying the insulator and contact materials in lateral dimensions that are greater than the lateral dimension of the stepped trench, and with the subsequent local removal so as to expose the surface of the first electrical contact layer. In this way, a series connection can be implemented much more quickly than according to the prior art.

After applying the insulator, or the contact material, notably in punctiform regions, the method has the potential to produce solar cells that have a large surface area for power generation.

Thus, novel solar cells having structured insulator regions that are filled with contact material are provided.

An ink jet printing method is particularly preferred for filling the stepped trenches with insulator and contact materials. An ink jet printer can be used for printing both conductive silver ink and insulating printer ink. If it is computer-controlled, the printer can further expedite the entire method.

The insulator material and/or the contact material for the series connection can also be applied by means of masks and spray techniques and/or photolithography techniques, or suitable screen printing techniques, spin coating and the like.

Depending on the laser that is employed and the wavelength thereof, material-selective laser ablation is employed, during which both the semiconductor material of the active semiconductor layers and the first and/or second electrical contact layers, or the insulator material, or the contact material, can be removed. A laser head having two or more lasers can be employed. Laser ablation as defined by the invention is preferably carried out in a computer-controlled manner.

The insulator is provided over the entire surface area or in a stripe shape over the entire length of the photovoltaic elements, or only in regions, for example in punctiform manner, in the first stepped trenches and on the surface of the second electrical contact layer.

A stripe-shaped arrangement of the insulator in the stepped trenches is advantageously rapid, and a punctiform arrangement of the insulator in the stepped trenches particularly advantageously increases the surface area for the conversion and generation of energy, which is available to produce energy. A full-surface-area arrangement of the insulator, including on the surface of the second electrical contact layer, is particularly imprecise and therefore very fast. The thickness of the insulator can be a few nanometers to several micrometers.

The contact material can likewise be provided in regions, which is to say in a stripe shape over the entire length of the photovoltaic elements, or in a punctiform or finger-shaped manner, from the surface of the second electrical contact layer of a photovoltaic element to the exposed surface of the first electrical contact layer of a photovoltaic element adjacent thereto. The contact material can also be provided over the entire surface area and may cover the surface of the layer structure.

The contact material used can be chromium, and silver and aluminum are preferred.

Punctiform arrangements of the insulator and the structuring thereof, as well as the arrangement of the contact material in the insulator, are preferably provided in a perforation-like manner over the length of the photovoltaic elements.

A variety of combinations are conceivable, by which the insulator can be structured according to the invention and the contact material can be provided and/or structured, without creating short circuits. Table 1 provides an overview.

If the insulator is provided on the layers in the stepped trenches, and also over the entire surface area of the surface of the second electrical contact layer, then the surface of the first electrical contact layer in the stepped trenches, and optionally the surface of the substrate located therein, as well as, adjacent to the stepped trenches, the surface of the second electrical contact layer are exposed once again by locally removing the insulator. This creates perforation-like regional cut-outs in the insulator in the region of the stepped trenches and, adjacent thereto, on the surface of the second electrical contact layer. The cut-outs in the region of the first stepped trenches are formed such that short circuits are prevented thereafter by the remaining insulator material. This means that semiconductor material and material of the second electrical contact layer in the stepped trenches are not exposed. Contact material can then be deposited once again onto the entire surface area of this layer structure and introduced in the stepped trenches and applied as a top layer. Because this step is also conducted without precision, and contact material is provided on the entire surface of the layer structure, this step is also carried out very quickly. Finally, in a structuring step, the surface of the second electrical contact layer is then exposed in suitable locations and the series connection is completed, without the possibility of short circuits occurring. Advantageously, the contact material is removed from the second electrical contact layer so as to achieve series connection of the photovoltaic elements.

By selecting a material for the second electrical contact layer that has lower conductivity than that of the first electrical contact layer, advantageously less light is absorbed in the regions of the contact layers.

The insulator that is selected can be what is known as a “white reflector”, for example white color 3070 from Marabu. This particularly advantageously causes the reflection and diffusion of light back into the solar cell to be increased.

The aforementioned regions are preferably punctiform and are preferably provided over the entire length of the photovoltaic elements in a perforation-like manner.

Solar modules comprising a plurality of photovoltaic elements, which are disposed parallel to one another and between which insulator material is provided, are produced. The insulator material is structured. Contact material, which brings the second electrical contact layer of a photovoltaic element A in contact with the first electrical contact layer of an adjoining element B, is provided in the insulator material. All photovoltaic elements are thus connected in series with one another. The contact material, which brings the second electrical contact layer of a photovoltaic element in contact with the first electrical contact layer of an adjoining element, is present either in stripe-shaped form over the entire length of the photovoltaic element, or in a punctiform shape in regions. The contact material, which brings the second electrical contact layer of a photovoltaic element in contact with the first electrical contact layer of an adjoining element, may also be provided over the entire surface area of the second electrical contact layer. It then comprises structuring close to the stepped trenches, which ensures that the photovoltaic elements are series-connected with one another, without the possibility of short circuits occurring.

The insulator and/or contact material for the series connection as defined by the invention is preferably applied in a computer-controlled manner.

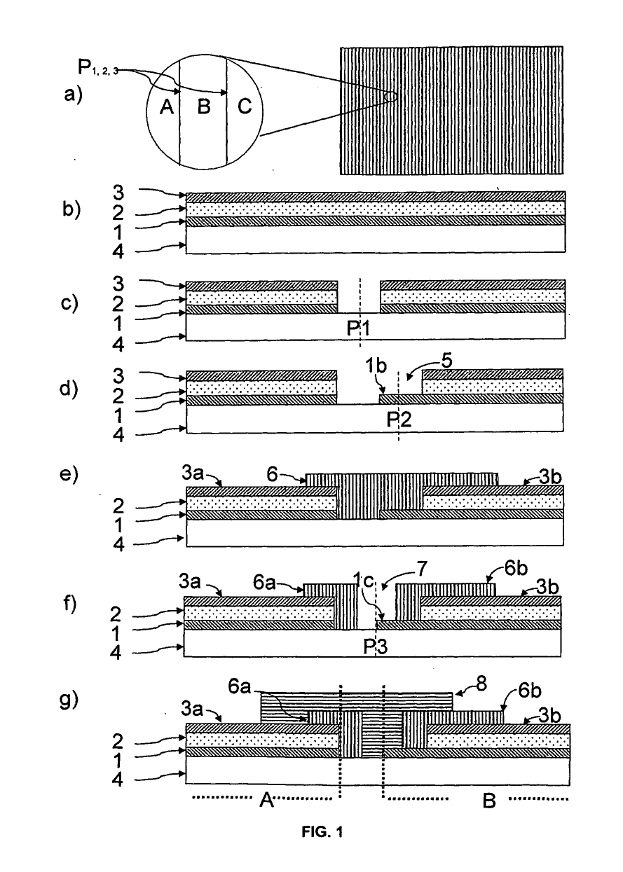

The invention will be described in more detail hereafter based on five exemplary embodiments and the accompanying FIGS. 1 to 5, without thereby limiting the invention.

In the drawings:

FIGS. 1 to 3: Generation and series connection of preferred stripe-shaped photovoltaic elements to form a solar module. The insulator 6, 26, 36 is provided in the form of a stripe over the entire length of the photovoltaic elements in the first stepped trenches and on the surface of the second electrical contact layer. The same applies to the contact material.

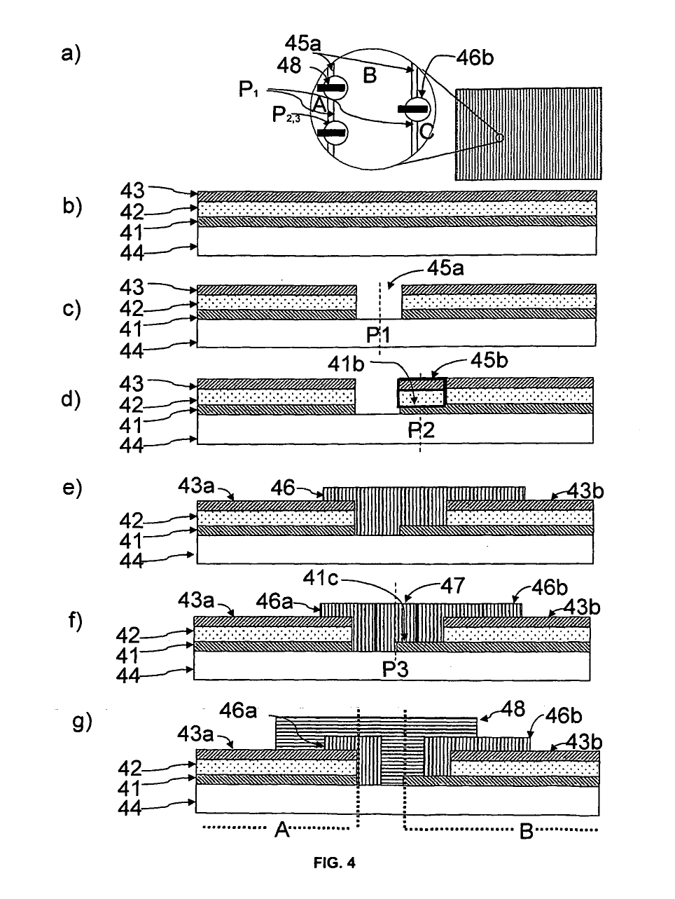

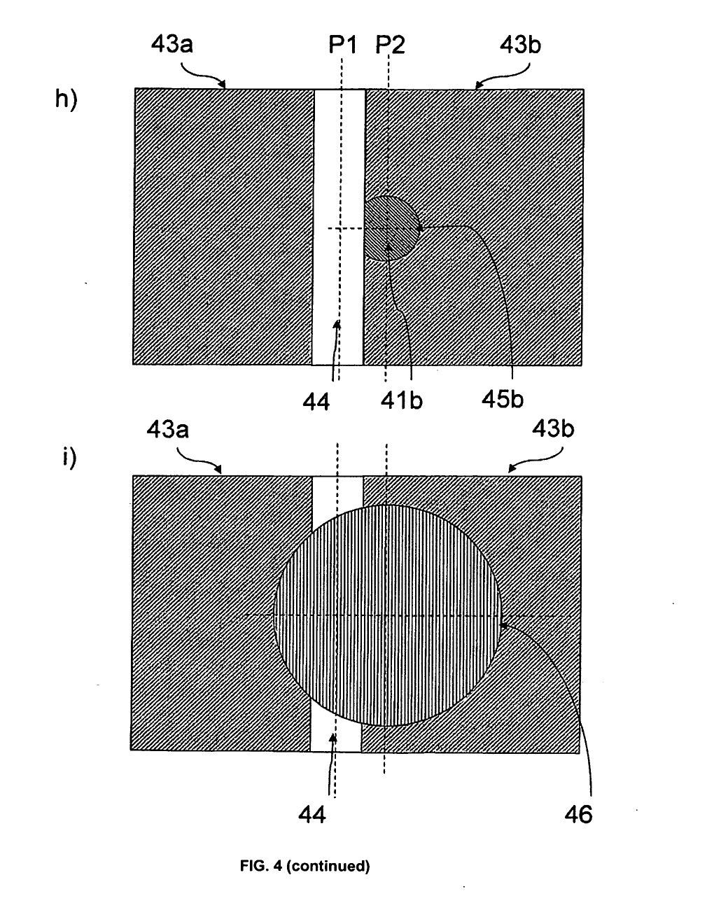

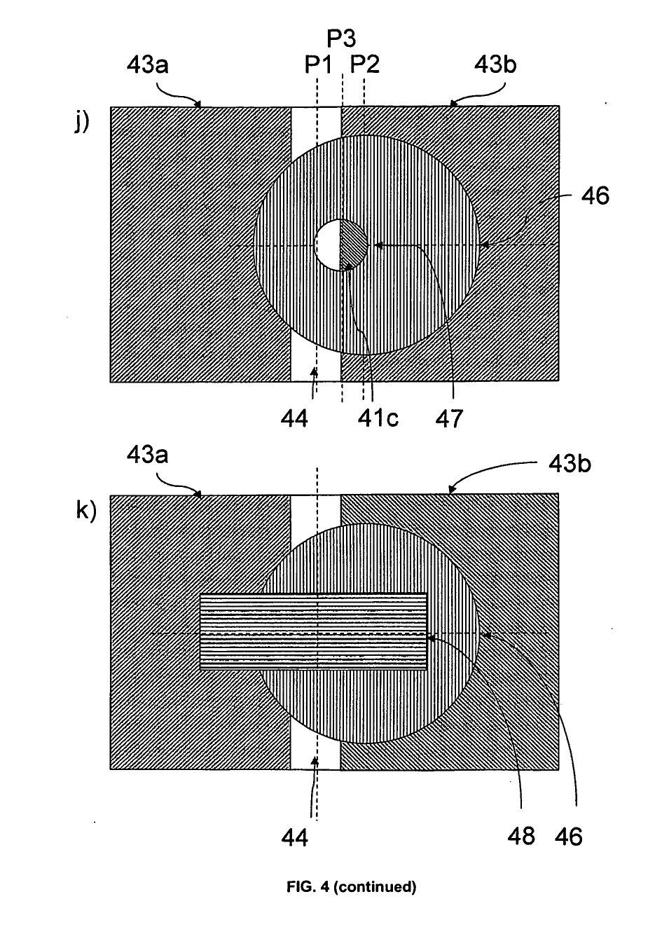

FIG. 4: Generation and series connection of preferred stripe-shaped photovoltaic elements to form a solar module, wherein the insulator 46 is provided preferably in punctiform manner in the first stepped trenches and on the surface of the second electrical contact layer. The same applies to the contact material.

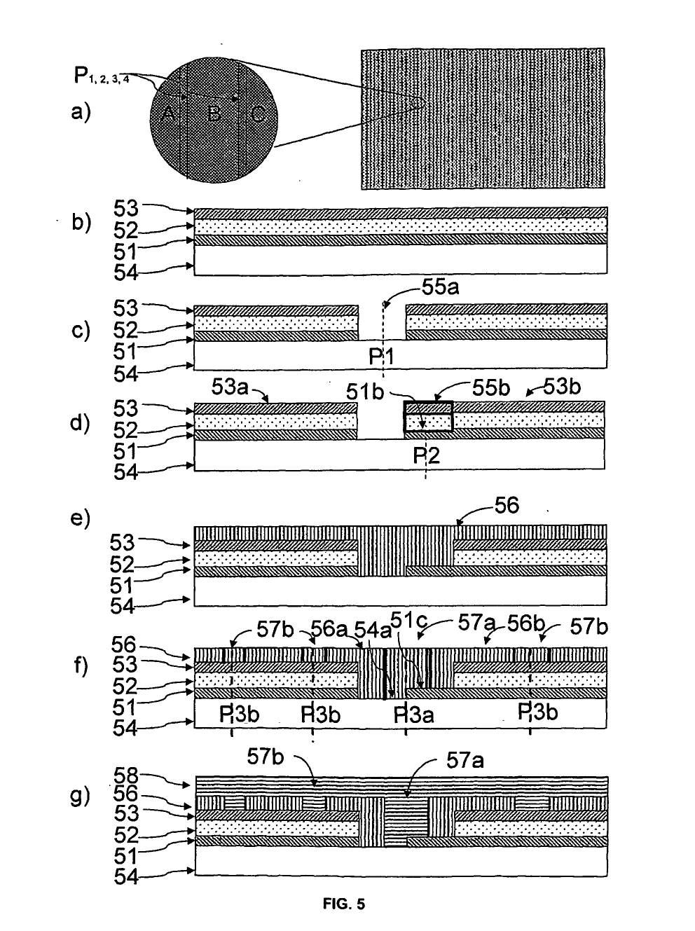

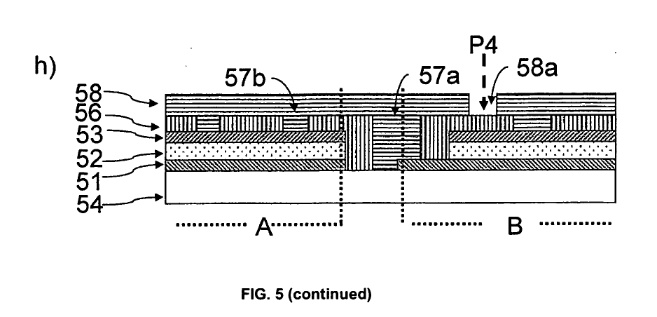

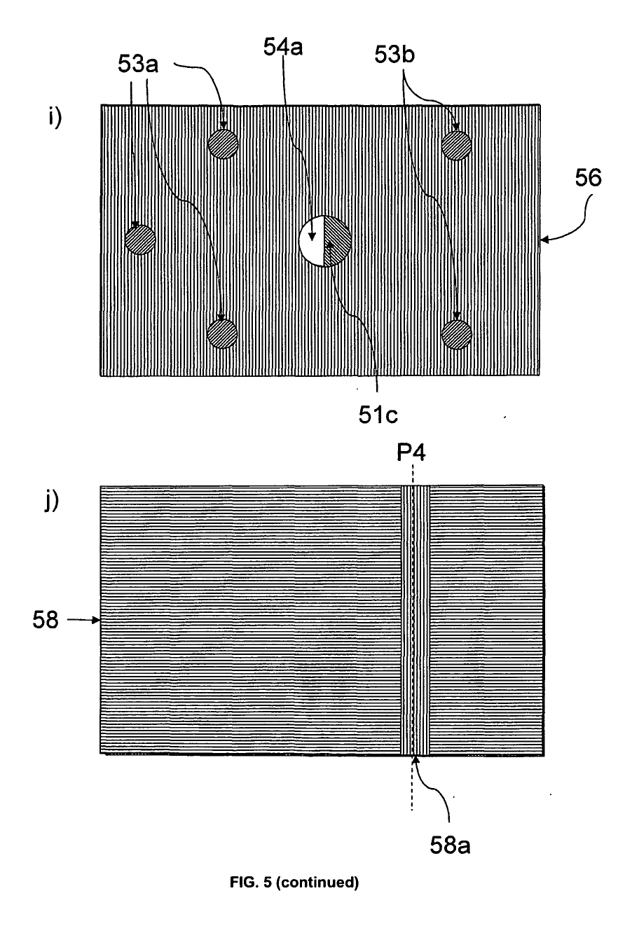

FIG. 5: Generation and series connection of preferred stripe-shaped photovoltaic elements to form a solar module, wherein the insulator 56 is provided over the entire surface area of the first stepped trenches and over the entire surface area of the surface of the second electrical contact layer. The same applies to the contact material.

FIGS. 1a) to 5a), on the right in the respective figure, show top views of several stripe-shaped photovoltaic elements in a solar module. An enlarged detail shows the respective three photovoltaic elements A to C disposed parallel to one another. The two lines represent stepped trenches between the elements. The designations P1 to P4 in FIGS. 1 to 5 denotes the approximate positions and the numbers of structurings of each stepped trench. The stripe-shaped photovoltaic elements A, B, C . . . are composed of the first and second electrical contact layers and the semiconductor layers interposed between them, as well as optional additional layers.

FIGS. 1b) to 5b) show the respective starting point of the method. A first electric TCO (transparent conductive oxide) contact layer 1, 21, 31, 41, 51 is provided over the entire surface area of a superstrate 4, 24, 34, 44, 54, which serves as the substrate, having a thickness of approximately 1.1 millimeters. The first electrical contact layer has a thickness of approximately 600 nanometers.

The active semiconductor layers 2, 22, 32, 42, 52 are provided on the surface of the first electrical contact layer 1, 21, 31, 41, 51 in the form of a p-i-n or a p-i-n-p-i-n structure, or the like. The semiconductor layers comprise at least one p-doped, at least one undoped and at least one n-doped layer.

The second electrical contact layer 3, 23, 33, 43, 53, serving as the back contact, which here is a metal layer or a multi-layer semiconductor-metal layer system having a thickness of approximately 280 nanometers, is provided on the side of the active semiconductor layers 2, 22, 32, 42, 52 which is located opposite of the first electrical contact layer 1, 21, 31, 41, 51.

Glass having a base area of 100 cm² is selected as the substrate 4, 24, 34, 44, 54. The first electrical contact layer 1, 21, 31, 41, 51 comprising ZnO was deposited thereon in a first deposition process. At least one p-i-n structure, and preferably a p-i-n-p-i-n structure or the like, is deposited as the active layers 2, 22, 32, 42, 52, preferably comprising silicon, on the first electrical contact layer 1, 21, 31, 41, 51 and is doped with boron and phosphorus by way of suitable doping. The second electrical contact layer 3, 23, 33, 34, 35 comprising ZnO and silver is deposited on the active semiconductor layers by means of PVD. The temperature and other process parameters that result in the starting situation shown in FIGS. 1b) to 5b) are disclosed in the prior art. A PECVD (plasma enhanced chemical vapor deposition) method, or another method, may be selected for depositing the layers.

### First Exemplary Embodiment

A microcrystalline solar cell, which is produced on a glass substrate measuring 10×10 cm² and having a thickness of 1.1 mm, is used as the basis for the exemplary embodiment. The thickness of the microcrystalline p-i-n layer stack serving as the active semiconductor layer 2 in FIG. 1 is approximately 1300 nanometer in total.

The microcrystalline layer stack is provided on a first electrical contact layer 1 that comprises zinc oxide, which has been textured by way of a wet-chemical process, and has a thickness of approximately 800 nanometers. A layer system comprising 80 nm zinc oxide in combination with a 200 nm thick silver layer is used as the second electrical contact 3. Here, first the zinc oxide layer, followed by the silver layer, are present on the silicon layer stack on the side of the second electrical contact layer.

In a first structuring process P1 (FIG. 1c)), the material is removed from the second electrical contact layer 3 and from the active semiconductor layers 2, as well as from the first electrical contact layer 1, by way of laser ablation, whereby the surface of the substrate 4 is exposed, in the trenches, over the entire length of the photovoltaic elements. This structuring process P1 is carried out consecutively for all photovoltaic elements. The laser is guided for this purpose over the surface of the substrate using a relative movement.

An Nd:YVO₄ laser from Rofin, of the RSY 20E THG type, is employed as the laser for ablating the material from layers 1, 2 and 3. The wavelength of the laser is 355 nm. This wavelength is specific to the ablation of the materials of layers 1 to 3. An average output power of 390 mW at a pulse repetition rate of 15 kHz is selected. The velocity of the relative movement between the laser beam and substrate is 580 mm/s. The duration of the individual pulses is approximately 13 ns. The laser radiation is focused on the layer side of the substrate using a focusing unit that has a focal distance of approximately 100 mm. To this end, the beam is conducted, from the substrate side, at the layers to be ablated through the transparent substrate. The intensity distribution of the focused beam is substantially Gaussian, wherein each pulse produces a circular ablation having a diameter of approximately 53 μm.

A plurality of trenches separating the photovoltaic elements A, B, C, and so forth, are thus present on the substrate 4, parallel to one another—see FIG. 1a and the vertical lines in the panel on the right. Following the structuring process P1, a respective trench is located between two directly adjoining photovoltaic elements A, B or B, C. The structuring process P1 is carried out by way of computer-assisted control.

After the step P1, each of the trenches has a lateral extension of approximately 53 micrometers. The structuring process P1 is repeated a number of times equal to the number of photovoltaic elements that are to be generated, such as 8 to 12.

A second structuring process P2 is carried out along the dotted line in FIG. 1d) so as to create the stepped trenches 5. To this end, the second electrical contact layer 3 and the portion of the active semiconductor layers 2 located beneath are ablated down to the surface of the first electrical contact layer 1. For this purpose, the material can be ablated to the edge of the first structuring trench P1.

The laser that is employed is an Nd:YVO₄ laser from Rofin, of the RSY 20E SHG type. The wavelength of the laser is 532 nm. This wavelength is specific to the ablation of the materials of the two layers 2, 3. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layers to be ablated through the transparent substrate. The intensity distribution of the focused beam is substantially Gaussian, wherein each pulse produces a circular ablation having a diameter of approximately 70 μm. So as to create a stripe-shaped trench having a width of approximately 120 μm, two ablations having minor overlap are carried out so as to separate two photovoltaic elements.

Subsequent to the second structuring process P2, the photovoltaic elements A, B, C are separated from one another down to the substrate 4. As a result, the stripe-shaped, parallel photovoltaic elements A, B, C, and so forth, are present on the substrate 4 electrically and spatially separated from one another by the stepped trenches 5. A plurality of first stepped trenches 5 for separating the photovoltaic elements A, B, C, and so forth, are thus created. The total width of the stepped trenches 5 is approximately 180 μm.

In the first stepped trenches 5, the surfaces of the first electrical contact layer 1b and of the substrate 4 are present directly adjacent to one another, so that in the section shown in FIG. 1d) a shoulder in the form of the shown step is created. Because structurings P1 and P2 extend over the length of the photovoltaic elements, each stepped trench 5 divides the stripe-shaped photovoltaic elements A and B, and so forth, (see FIG. 1b)-g)) from one another along the entire length of the solar module, see FIG. 1a). The stepped trench 5 shown is one-sided because in it the surface 1b of the first contact layer 1 is exposed only on one side to the right above the substrate 4. The structuring process P2 is repeated in accordance with the structuring P1 until the layers 1, 2, 3 are provided for a plurality of stripe-shaped, parallel photovoltaic elements A, B, C, and so forth, separated by the individual stepped trenches 5.

Thereafter the insulator 6, which is a paint, is applied to the stepped trenches 5 beyond the flanks of the stepped trench 5 on both sides. This means that the insulator is provided laterally over the flanks of the stepped trenches up to the surface 3a, 3b of the second electrical contact layer 3, and thus also on this layer. The paint that is employed as the insulator 6 is Dupli-Color Aerosol Art from Motip Dupli GmbH in the hue RAL 9005. The insulator can be applied using a spraying technique. The insulator thickness is approximately 8 μm. The insulator is applied using a metal mask, which has the geometry that is required for the arrangement of the insulator. The metal mask has stripe-shaped openings measuring approximately 4 mm in width. The openings recur at regular intervals in accordance with the distances of the stepped trenches 5 on the substrate from one another. The length of the openings of the mask is approximately 5 mm larger on both sides than the length of the stepped trenches 5. The use of the mask results in a stripe-shaped insulator geometry in accordance with FIG. 1e). As a result of the orientation of the mask, one of the two sides, which here is the side comprising the surface 3a of the second electrical contact layer 3, can be covered less by way of lateral extension with the insulator stripe 6, which is a non-conductive material, than the opposing other side comprising the surface 3b. The surface 3a on the left of the figure is covered by way of lateral extension to approximately 1300 μm by the insulator. The lateral extension of the surface 3b (on the right in the figure) comprising the insulator, in contrast, is approximately 2500 μm.

The application of the insulator 6 and the selection of the mask are such that all stepped trenches 5 are filled, and the surfaces 3a and 3b of the second electrical contact layer 3 are covered in a stripe-shaped manner with the insulator 6 inside the module (FIG. 1a, on the right of the figure).

A structuring process P3 is carried out for each stepped trench. The insulator 6 is removed in the trenches 5 over the length of the photovoltaic elements by creating trenches 7. The trench 7 is created so as to be located between the right outer edge and the left edge of the stepped trench 5. This means that the lateral flanks of the stepped trenches remain insulated. Electric short circuiting is thus prevented. Moreover, P3 is positioned so that the first electrical contact layer 1c inside the stepped trench 5 is exposed. The removal is carried out by means of selective laser ablation, selecting an Nd:YVO₄ laser from Rofin, of the RSY 20E SHG type. The output power of the laser is 860 mW, at a pulse repetition frequency of 17 kHz, and the wavelength is 532 nm. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the substrate side through the transparent substrate to the layer to be ablated. The intensity distribution of the focused beam is substantially Gaussian, wherein each pulse produces a circular ablation having a diameter of approximately 100 μm. The laser creates a second stepped trench 7 inside the previously filled-in first stepped trench 5 (FIG. 10). This again exposes the surface of the first electrical contact layer 1c and the surface of the substrate 4 directly adjacent to one another in the manner of a shoulder or step. Because this structuring process P3 is again carried out over the length of the photovoltaic elements, a second stepped trench 7 is present, which is offset from the first stepped trench 5. This means that the left ridge 6a and the right ridge 6b of the insulator material remain for electrically insulating cells A, B, and so forth. The perpendicularly extending edge ridges 6a and 6b of the insulator remaining after the structuring process P3 subsequently prevent short circuiting of the two photovoltaic elements A and B.

The structuring process P3 is repeated as often as the structuring processes P1 and P2 and until the layers 1, 2, 3 are present as a plurality of stripe-shaped, parallel photovoltaic elements, separated by the stepped trenches 7 and separated by the edge ridges 6a and 6b of the insulator.

In the final step, every second stepped trench 7 is filled in a stripe-shaped manner with contact material 8 over the length of the photovoltaic elements. The exposed surface 1c of the first electrical contact layer of the photovoltaic element B in the second stepped trench 7 is electrically contacted only with the surface of the second electrical contact layer 3a of the adjoining photovoltaic element A (FIG. 1g)), but is not short-circuited with its own surface.

The electrical contact between the surface of the second electrical contact layer 3a of element A and the surface of the first electrical contact layer 1c of element B, and hence the series connection of the two photovoltaic elements A and B, is thus completed.

Silver having a thickness of approximately 200 nm is selected, for example, as the contact material. The second stepped trench 7 is likewise filled using mask techniques. To this end, a mask, which is similar or identical to the mask used to apply the insulator, is employed. The silver is structured by way of the mask using a thermal evaporation process and is applied to the substrate. The second stepped trench 7 is filled in with contact material 8 in a stripe-shaped manner, so that only the surface of the second electrical contact layer 3a of a photovoltaic element A, and not the surface of the second electrical contact layer 3b of the adjoining photovoltaic element B, is connected, in the stepped trench 7, to the exposed surface of the first electrical contact layer 1c of element B. This is achieved by a slightly offset orientation of the mask by approximately 2 mm, as compared to the orientation of the mask when applying the insulator.

The filling of the second stepped trench 7 with contact material 8 and the selection of the mask are performed along all stripes in such a way (see FIG. 1a)) that all adjoining photovoltaic elements inside the module are thus connected in series to one another.

### Second Exemplary Embodiment

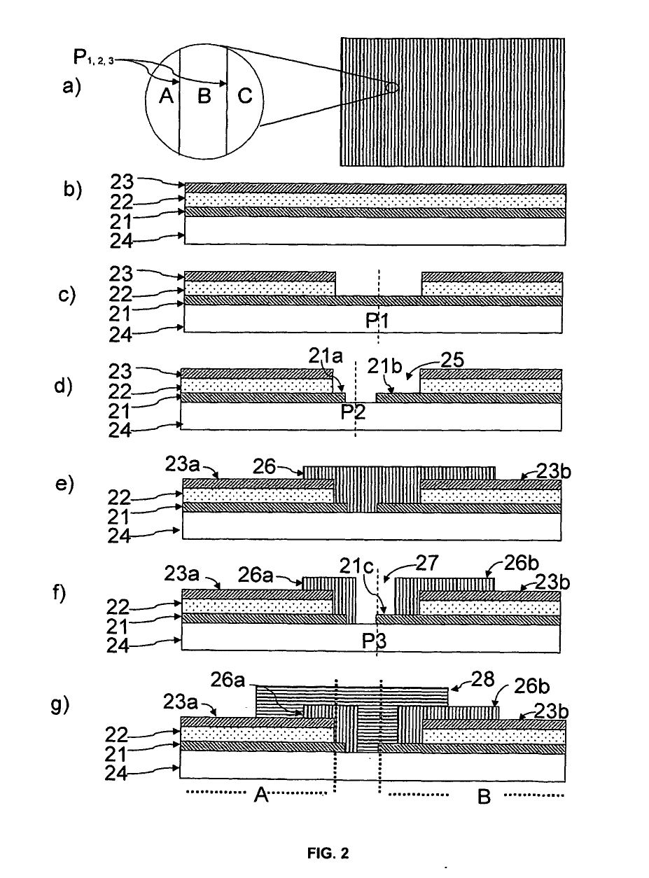

A solar cell, which is produced on a glass substrate measuring 10×10 cm² and having a thickness of 1.1 mm, is used as the basis for the second exemplary embodiment. The thickness of the microcrystalline p-i-n layer stack 22 serving as the active semiconductor layer in FIG. 2 is approximately 1300 nm in total. The microcrystalline layer stack is provided on a first electrical contact layer 21 that comprises zinc oxide, which has been textured by way of a wet-chemical process, and has a thickness of approximately 800 nanometers.

A layer system comprising 80 nm zinc oxide in combination with a 200 nm thick silver layer is used as the second electrical contact layer 23. Here, first the zinc oxide layer, followed by the silver layer, are present on the silicon layer stack 22 on the side of the second electrical contact layer.

In a first structuring process P1 (FIG. 2c)), material is removed from the second electrical contact layer 23 and from the active semiconductor layers 22 by way of laser ablation, see FIG. 2a) and FIG. 2c), whereby the surface of the first electrical contact layer 21 is exposed in the trenches over the length of the photovoltaic elements. This structuring process P1 is carried out consecutively for all photovoltaic elements. The laser is guided for this purpose over the surface of the substrate using a relative movement.

An Nd:YVO₄ laser from Rofin, of the RSY 20E SHG type, is employed as the laser for ablating the material from layers 22 and 23. The wavelength of the laser is 532 nm. This wavelength is specific to the ablation of the materials of the two layers 22, 23. An average output power of 410 mW at a pulse repetition rate of 11 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted, from the substrate side, at the layers to be ablated through the transparent substrate. The intensity distribution of the focused beam is substantially Gaussian, wherein each pulse produces a circular ablation having a diameter of approximately 70 μm. So as to create a trench having a width of approximately 200 μm, three stripe-shaped ablations having minor overlap are carried out so as to separate two photovoltaic elements.

A plurality of trenches for the photovoltaic elements A, B, C, and so forth, are thus present on the first electrical contact layer 21 parallel to one another other over the length of the photovoltaic elements and next to one another, see FIG. 2c) and the vertical lines in the module on the right of FIG. 2a). Following the structuring process P1, a respective trench is located between two directly adjoining photovoltaic elements A, B or C, B, and so forth. The structuring process P1 is carried out by way of computer-assisted control.

After P1, each of the trenches has a lateral extension of approximately 200 micrometers. The structuring process P1 is repeated a number of times equal to the number of photovoltaic elements that are to be generated. In total, approximately 8 to 12 trenches can be created, for example.

The first electrical contact layer 21 is ablated up to the surface of the substrate 24 by means of a second structuring process P2 along the dotted line so as to create the stepped trench 25 (FIG. 2d)). The distance between the center of the separation of the first electrical contact layer and the outermost left edge of the stepped trench 25 here is approximately 60 μm.

An Nd:YVO₄ laser from Rofin, of the RSY 20E THG type, having a wavelength of 355 nm is selected as the laser. This wavelength is specific to the ablation of the material of layer 21. An average output power of 300 mW at a pulse repetition rate of 15 kHz is selected. The velocity of the relative movement between the laser beam and substrate is 250 mm/s. The duration of the individual pulses is approximately 13 ns. The laser radiation is focused on the layer side of the substrate using a focusing unit that has a focal distance of 100 mm. To this end, the beam is conducted from the substrate side through the transparent substrate to the layer to be ablated. The intensity distribution of the focused beam is substantially Gaussian, wherein each pulse produces a circular ablation having a diameter of approximately 35 μm. Subsequent to the second structuring process P2, the photovoltaic elements A, B, C, and so forth, are separated from one another down to the substrate 24. As a result, the stripe-shaped, parallel photovoltaic elements A, B, C, and so forth, are present on the substrate 24, electrically insulated from one another by the trenches 25. A plurality of first stepped trenches 25 for separating the photovoltaic elements A, B, C, and so forth, are thus created.

In the first stepped trenches 25, the surfaces of the first electrical contact layer 21a, 21b and of the substrate 24 are present directly adjacent to one another over the length of the photovoltaic elements, so that a shoulder in the form of a step is created. Because P2 is a structuring along the entire surface of the layer structure the two-sided stepped trench 25 divides the two photovoltaic elements A and B shown in the figure from one another along the entire longitudinal axis of the solar module (see FIG. 2a), right side).

The stepped trenches 25 that are produced are two-sided because the surfaces 21a, 21b of the first contact layer are exposed on two sides above the substrate 24 in the stepped trenches 25.

The structuring process P2 is repeated in accordance with the structuring process P1 until the layers 21, 22, 23 are present for a plurality of stripe-shaped, parallel photovoltaic elements A, B, C, and so forth, separated by the individual stepped trenches 25.

Thereafter, an insulator 26, which is a paint, is applied to the stepped trenches 25 beyond the edge of each stepped trench 25 on either side. This means, that the insulator is provided laterally over both flanks of the stepped trenches up to the surface 23a, 23b of the second electrical contact layer 23, and on this layer. The paint that is employed as the insulator 26 is Dupli-Color Aerosol Art from Motip Dupli GmbH in the hue RAL 9005. The insulator can be applied using a spraying technique. The insulator thickness is approximately 8 μm. The insulator is applied using a metal mask, which has the geometry that is required for structuring the insulator. The metal mask has stripe-shaped openings measuring approximately 4 mm in width. The openings recur at regular intervals in accordance with the distances of the stepped trenches 25 on the substrate from one another. The length of the openings of the mask on both sides is approximately 5 mm larger than the length of the stepped trenches 25. By using the mask, an insulator geometry in accordance with FIG. 2e) can be produced. As a result of the orientation of the mask, one of the two sides, which here is the side comprising the surface 23a of the second electrical contact layer 3, can be covered less in the lateral extension by the insulator stripe 26, which is a non-conductive material, than the opposing other side comprising the surface 23b. The surface 23a on the left of the figure is covered by way of a lateral extension of 1300 μm by the insulator. The lateral extension on the surface 23b (on the right in the figure) comprising the insulator with overlap, in contrast, is approximately 2500 μm for each stepped trench.

The application of the insulator and the selection of the mask are performed such that all stepped trenches 25 and the surfaces 23a and 23b of the second electrical contact layer are covered in a stripe-shaped manner by the insulator 26 inside the module (see FIG. 2a), on the right of the figure).

Another structuring process P3 then follows for each stepped trench. The insulator 26 is removed selectively in the form of a stripe in the trenches 25 over the length of the photovoltaic elements. As a result of the structuring P3, the respective trench 27 is created and positioned so as to be located between the right and left outer edges of the stepped trench 25. The lateral flanks of the stepped trench 27 are covered by the insulator 26a and 26b. Electrical short circuiting is thus prevented. The removal is performed by means of selective laser ablation, selecting an Nd:YVO₄ laser from Rofin, of the RSY 20E SHG type. The output power of the laser here is 860 mW, at a pulse repetition frequency of 17 kHz, and the wavelength is 532 nm. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the substrate side through the transparent substrate, to the layer to be ablated. The intensity distribution of the focused beam is substantially Gaussian, wherein each pulse produces a circular ablation having a diameter of approximately 100 μm. The laser creates a second stepped trench 27 inside the previously filled-in first stepped trench 25 (FIG. 2f)). This once again exposes the surface of the first electrical contact layer 21c and the surface of the substrate 24 directly adjacent to one another in the manner of a shoulder or step. Because this structuring process P3 is carried out again over the length of the photovoltaic elements, a second stepped trench 27 is present, which is offset from the first stepped trench 25. This means that the left ridge 26a of the insulator material remains for electrically insulating the cells A, B. The perpendicularly extending edge ridges 26a and 26b of the insulator remaining after the structuring P3 thereafter prevent short circuiting of the two photovoltaic elements A and B.

The structuring P3 is repeated as often as the structurings P1 and P2 and until the layers 21, 22, 23 are present in a plurality of stripe-shaped, parallel photovoltaic elements, separated by the stepped trenches 27 and separated by the edge ridges 26a and 26b of the insulator.

In the final step, every stepped trench 27 is filled in a stripe-shaped manner with contact material 28 over the length of the photovoltaic elements. This filling is done such that the exposed surface 21c of the first electrical contact layer of the photovoltaic element B in the second stepped trench 27 is electrically contacted only with the surface of the second electrical contact layer 23a of the adjoining photovoltaic element A (FIG. 2g)). The electrical contact between the surface of the second electrical contact layer 23a and the surface of the first electrical contact layer 21c, and hence the series connection of the two photovoltaic elements A and B, are thus completed.

The contact material used is, for example, silver having a thickness of approximately 200 nm. The second stepped trench 27 is likewise filled using mask techniques. To this end, a mask that is identical to the mask used to apply the insulator is employed. The silver is applied to the substrate in a structured manner by way of the mask using a thermal evaporation process. The second stepped trench 27 is filled with or covered by contact material 28 so that only the surface of the second electrical contact layer 23a of the photovoltaic element A, and not the surface of the second electrical contact layer 23b of the photovoltaic element B, is connected to the exposed surface of the first electrical contact layer 21c in the stepped trench 27. This is achieved by a slightly offset orientation of the mask, by approximately 2 mm as compared to the orientation of the mask when applying the insulator.

The filling of the stepped trench 27 with contact material 28 and the selection of the mask are such that, along all stripes, over the length of the photovoltaic elements (see FIG. 2a)), all photovoltaic elements inside the module are connected in series to one another.

### Third Exemplary Embodiment

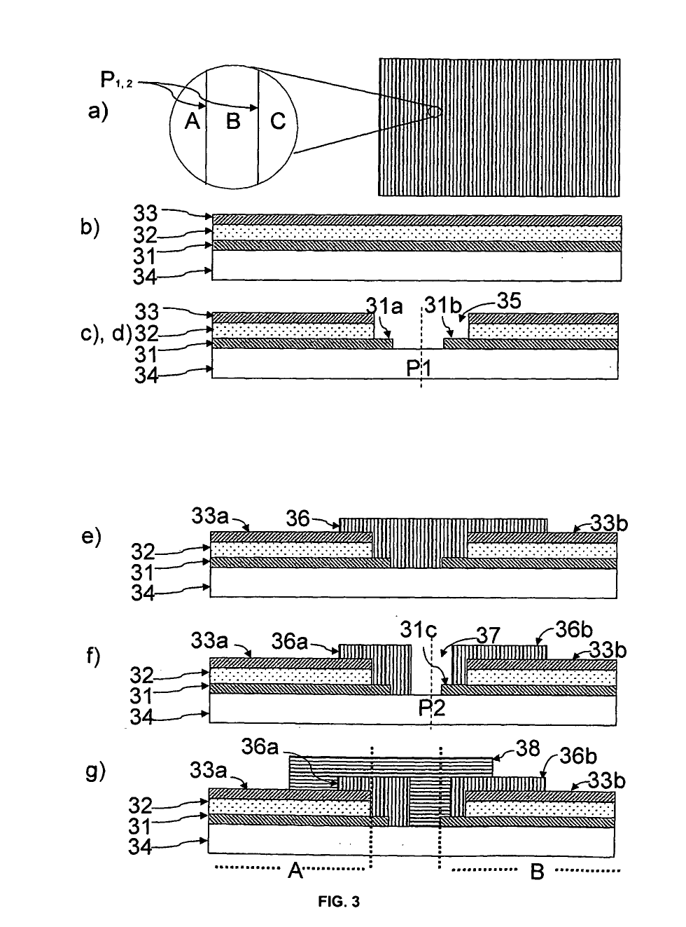

A microcrystalline solar cell, which is produced on a glass substrate measuring 10×10 cm² and having a thickness of 1.1 mm, is used as the basis for the exemplary embodiment. The thickness of the microcrystalline p-i-n layer stack 32 (active semiconductor layer, FIG. 3) here is approximately 1300 nanometers in total. The microcrystalline layer stack is located on a first electrical contact layer 31 that comprises zinc oxide, which has been textured by way of a wet-chemical process, and has a thickness of approximately 800 nm. A layer system comprising 80 nm zinc oxide in combination with a 200 nm thick silver layer is used as the second electrical contact layer 33. Here, first the zinc oxide layer, followed by the silver layer, are present on the silicon layer stack on the side of the second electrical contact layer.

In a first structuring process P1 (FIGS. 3c, 3d)), material is removed from the second electrical contact layer 33, and also from the active semiconductor layers 32 and the first electrical contact layer 31, by a single laser ablation process, whereby the surface of the first electrical contact layer 31 is exposed in a stripe-shaped manner over the length of the photovoltaic elements. This structuring process P1 is carried out consecutively for all photovoltaic elements A, B, C, and so forth. For this purpose, two laser beams having differing wave lengths and focus geometries are simultaneously guided over the surface of the substrate using a relative movement. The distance and output powers are adjusted so that the material of layers 33 and 32 and 31, or 33 and 32 is removed simultaneously.

An Nd:YVO₄ laser from Rofin, of the RSY 20E SHG type, is employed as the laser for ablating the material from layers 32 and 33. The wavelength of the laser is 532 nm. This wavelength is specific to the ablation of the materials of the two layers 32, 33. An average output power of 1200 mW at a pulse repetition rate of 4 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the substrate side to the layer to be ablated, through the transparent substrate. The intensity distribution of the focused beam is substantially Gaussian, wherein each pulse produces a circular ablation having a diameter of approximately 200 μm. The diameter of the circular ablation was produced using a divergence lens and adjusted prior to focusing the laser beam. An Nd:YVO₄ laser from Rofin, of the RSY 20E THG type, having a wavelength of 355 nm is selected as the laser for ablating the material 31. This wavelength is specific to the ablation of the material of layer 31. An average output power of 550 mW at a pulse repetition rate of 20 kHz is selected. As a result of the design, the velocity of the relative movement between the laser beam and substrate is likewise 800 mm/s. The duration of the individual pulses is approximately 13 ns. The laser radiation is focused on the layer side of the substrate using a focusing unit, which is also employed to focus the laser radiation having the wavelength of 532 nm. To this end, the beam is conducted from the substrate side through the transparent substrate to the layer to be ablated. The intensity distribution of the focused beam is substantially Gaussian, wherein each pulse produces a circular ablation having a diameter of approximately 55 μm.

A plurality of stripe-shaped stepped trenches 35 for the photovoltaic elements A, B, C, and so forth, are thus present on the first electrical contact layer 31 parallel to one another (see FIG. 3a) and the vertical lines in the module on the right). Following the structuring process P1, a respective trench is located between two directly adjoining photovoltaic elements A, B or C, B, and so forth. The structuring process P1 is carried out by way of computer-assisted control. The structuring process P1 is repeated a number of times equal to the number of photovoltaic elements that are to be generated.

A second structuring P2 carried out temporally thereafter, such as that shown in FIGS. 1 and 2, is advantageously dispensed with. In P1, the first electrical contact layer 31 is ablated in one step along the dotted line down to the surface of the substrate 34 and the surface of the first electrical contact layer so as to create the stepped trench 35 (FIGS. 3c) and 3d)).

In the first stepped trenches 35, the surfaces of the first electrical contact layer 31a, 31b and of the substrate 34 are present directly adjacent to one another over the length of the photovoltaic elements, so that a respective shoulder in the form of a step is created. Because this structuring is again a structuring over the length of the photovoltaic elements, each two-sided stepped trench 25 separates the adjoining stripe-shaped photovoltaic elements A and B (see FIGS. 3b) to 3g)) from one another along the entire longitudinal axis of the solar module. The same applies to the remaining photovoltaic elements C, and so forth.

The stepped trenches 35 are two-sided because the surfaces 31a, 31b of the first contact layer are exposed in the stepped trenches 35 on two sides, which is to say on both sides above the substrate 34.

The structuring P1 is repeated until the layers 31, 32, 33 are present for a plurality of stripe-shaped, parallel photovoltaic elements A, B, C, and so forth, separated by the individual stepped trenches 35.

Thereafter, the insulator 36, which is a paint, is provided on both sides, beyond the edge of the stepped trench 35. This means that the insulator is provided laterally over the flanks of these stepped trenches up to the surfaces 33a, 33b of the second electrical contact layer 33, and thus on this layer. The paint that is employed as the insulator 36 is Dupli-Color Aerosol Art from Motip Dupli GmbH in the hue RAL 9005. The insulator can be applied by means of a spray technique. The resulting insulator thickness is approximately 8 μm. The insulator is applied using a metal mask, which has the necessary geometry. The metal mask has stripe-shaped openings measuring approximately 4 millimeters in width. The openings recur at regular intervals in accordance with the distances of the stepped trenches 35 from one another on the substrate. The length of the openings of the mask on either side is approximately 5 mm larger than the length of the stepped trenches 35. By using the mask, an insulator geometry in accordance with FIG. 3e) can be achieved over the length of the photovoltaic elements. As a result of the orientation of the mask, one of the two sides, which here is the side comprising the surface 33a of the second electrical contact layer 33, can be covered less by way of lateral extension by the insulator stripe 36, which is a non-conductive material, than the opposing other side comprising the surface 33b. The surface 33a on the left of the figure is covered by the insulator by way of a lateral extension of 1300 μm. The lateral extension of the surface 33b (on the right in the figure) comprising the insulator, in contrast, is approximately 2500 μm.

All parallel stepped trenches 35 and the surfaces 33a and 33b of the second electrical contact layer are covered in a stripe-shaped manner by the insulator 36 over the length of the photovoltaic elements inside the module (FIG. 1a), on the right in the figure).

The structuring P2 for each stepped trench then follows. The insulator 36 is selectively removed in a stripe-shaped manner in the former trenches 35 over the length of the photovoltaic elements. The new trench 37 is positioned as a result of P2 so as to be located between the right and left outer edges of the first stepped trench 35. The lateral flanks of the stepped trenches are insulated by the insulator 36a, 36b. Electric short circuiting is thus prevented. As a result of P2, the first electrical contact layer 31c, inside the stepped trench is exposed. The removal is carried out by means of selective laser ablation, selecting an Nd:YVO₄ laser from Rofin, of the RSY 20E SHG type. The output power of the laser here is 860 mW, at a pulse repetition frequency of 17 kHz, and the wavelength is 532 nm. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the substrate side, through the transparent substrate, to the layer to be ablated. The intensity distribution of the focused beam is substantially Gaussian, wherein each pulse produces a circular ablation having a diameter of approximately 100 μm. The laser creates a second stepped trench 37 inside the former, now filled-in, first stepped trench 35 (FIG. 3f)). This again exposes the surface of the first electrical contact layer 31c and the surface of the substrate 34 directly adjacent to one another in the manner of a shoulder or step over the length of the photovoltaic elements. Because P2 is again carried out over the entire length of the photovoltaic elements, a second stepped trench 37 is present, which is offset from the respective first stepped trench 35. The perpendicularly extending edge ridges 36a and 36b of the insulator remaining after P2 thereafter prevent short circuits in the two photovoltaic elements A and B.

P2 is repeated as many times as P1. The layers 31, 32, 33 are thereby divided into a plurality of stripe-shaped, parallel photovoltaic elements. These elements are separated by the stepped trenches 37 and separated by the insulator ridges 36a and 36b.

In the final step, the second stepped trenches 37 are filled, likewise in a stripe-shaped manner, with contact material 38 over the length of the photovoltaic elements. The exposed surface 31c of the first electrical contact layer of the photovoltaic element B is electrically contacted only with the surface of the second electrical contact layer 33a of the adjoining photovoltaic element A (FIG. 3g)). The surface 31c is not contacted by 33b.

The electrical contact between the surface of the second electrical contact layer 33a of a photovoltaic element A and the surface of the first electrical contact layer 31c of an adjoining photovoltaic element B, and hence the series connection of the two photovoltaic elements A and B, are thus completed.

The contact material that is provided is, for example, silver having a thickness of 200 nm. The second stepped trench 37 is likewise filled using mask techniques. To this end, a mask that is identical to the mask used to apply the insulator is employed. The silver is applied by way of the mask using a thermal evaporation process. To this end, the second stepped trenches 37 are filled with contact material 38 so that only the surface of the second electrical contact layer 33a of a photovoltaic element A, and not the surface of the second electrical contact layer 33b of the adjoining photovoltaic element B, is connected to the exposed surface of the first electrical contact layer 31c in the stepped trench 37. This is achieved by a slightly offset orientation of the mask, by approximately 2 mm as compared to the orientation of the mask when applying the insulator.

The filling of the second stepped trench 37 with contact material 38 and the selection of the mask are such that, along all stripes (see FIG. 3a)), all photovoltaic elements A, B, C, and so forth, inside the module are connected in series to one another.

It is particularly advantageous that one structuring step is saved in comparison with the first and second exemplary embodiments.

### Fourth Exemplary Embodiment

A microcrystalline solar cell, which is produced on a glass substrate measuring 10×10 cm² and having a thickness of 1.1 mm, is used as the basis for the exemplary embodiment. The thickness of the microcrystalline p-i-n layer stack, which serves as the active semiconductor layer 42, FIG. 4), here is approximately 1300 nanometers in total. The microcrystalline layer stack is provided on a first electrical contact layer 41 that comprises zinc oxide, which has been textured by way of a wet-chemical process, and has a thickness of approximately 800 nanometers. A layer system comprising 80 nm zinc oxide in combination with a 200 nm thick silver layer is provided as the second electrical contact layer 43. Here, first the zinc oxide layer, followed by the silver layer, are present on the silicon layer stack on the side of the second electrical contact layer.

As a result of the structuring P1 (FIG. 4c)), material is removed from the second electrical contact layer 43 and from the active semiconductor layers 42, as well as from the first electrical contact layer 41, by way of laser ablation in a stripe-shaped manner over the length of the photovoltaic elements, whereby the surface of the substrate 44 is exposed in the trenches 45a in a stripe-shaped manner. P1 is carried out consecutively for all photovoltaic elements. The laser is guided for this purpose over the surface of the substrate using a relative movement.

An Nd:YVO₄ laser from Rofin, of the RSY 20E THG type, is employed as the laser for ablating the material from layers 41, 42 and 43. The wavelength of the laser is 355 nm. This wavelength is specific to the ablation of the materials of layers 41 to 43. An average output power of 390 mW at a pulse repetition rate of 15 kHz is selected. The velocity of the relative movement between the laser beam and substrate is 580 mm/s. The duration of the individual pulses is approximately 13 ns. The laser radiation is focused on the layer side of the substrate using a focusing unit that has a focal distance of 100 mm. To this end, the beam is conducted from the substrate side to the layer to be ablated, through the transparent substrate. The intensity distribution of the focused beam is substantially Gaussian, wherein each pulse produces a circular ablation having a diameter of approximately 53 μm. The trenches 45a run over the length of the photovoltaic elements.

A plurality of trenches, such as 8 to 12, separating the photovoltaic elements A, B, C, and so forth, are thus present on the substrate 44 parallel to one another (see FIG. 4a: vertical, dotted lines in the module on the right as viewed from above). Following P1, a respective trench 45a is located between two directly adjoining photovoltaic elements A, B or C, B over the length of the photovoltaic elements. P1 is carried out by way of computer-assisted control. Each of the trenches 45a has a lateral extension of approximately 53 micrometers. P1 is repeated a number of times equal to the number of photovoltaic elements that are to be generated.

Contrary to the first three exemplary embodiments, in the fourth exemplary embodiment, stripe-shaped ablation of the active semiconductor layers 42 and of the second electrical contact layer 43 over the length of the photovoltaic elements, exposing the first electrical contact layer 41, is not performed. The second structuring P2 rather ablates the layers 42 and 43 only in regions, which is to say in a punctiform manner, for example, only on the right side along the trench 45a up to the surface of the first electrical contact layer 41 (see FIG. 4d)). The punctiform cut-outs 45b have a distance of approximately 1 millimeter to 5 millimeters from one another in the longitudinal direction of each stripe-shaped trench 45a. It is possible, however, to select different distances and sizes. Solely because of the cross-sectional view, the layers 42, 43 located behind the sheet plane are thus apparent in region 45b of FIG. 4d) in the bolded area. The top view of FIG. 4d) is shown in FIG. 4h) for a single punctiform cut-out 45b. In this region, the surface 41b of the first electrical contact layer is exposed.

An Nd:YVO₄ laser from Rofin, of the RSY 20E SHG type, is employed as the laser for ablating the material from layers 42 and 43. The wavelength of the laser is 532 nm. This wavelength is specific to the ablation of the materials of the two layers 42, 43. An average output power of 48 mW at a pulse repetition rate of 0.16 kHz is selected. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the substrate side to the layer to be ablated, through the transparent substrate. The intensity distribution of the focused beam is substantially Gaussian, wherein each pulse produces a circular ablation 45b having a diameter of approximately 200 μm. The diameter of the circular ablation was produced using a divergence lens and adjusted prior to focusing the laser beam.

Subsequent to P1 and P2, the photovoltaic elements A, B, C, and so forth, are separated from one another down to the substrate 44. As a result, the stripe-shaped, parallel photovoltaic elements A, B, C, and so forth, are present on the substrate 44, electrically insulated from one another by the stepped trenches 45a, 45b. A plurality of (for example, 8 to 12) parallel first trenches 45a are created over the length of the photovoltaic elements, having a number of punctiform cut-outs 45b along each trench 45a (FIG. 4d), FIG. 4h)).

In the cut-outs 45b, the surfaces of the first electrical contact layer 41b and of the substrate 44 are present directly adjacent to one another (FIGS. 4d) and 4h)), so that a shoulder in the form of a local stepped trench 45a, 45b is created. Because this structuring P2 is a punctiform structuring along one side of the trench 45a, the semiconducting layers 42 and the second electrical contact layer 43 of element B are preserved over a large region of the module for energy generation.

The punctiform cut-outs 45b on the trenches are one-sided, because the surface 41b of the first contact layer is exposed there only on one side above the exposed substrate surface. The cut-outs 45b have a diameter of approximately 200 μm. Depending on the distance, as many as 100 cut-outs per trench can be created, for example. P2 is thus repeated several times along the trench 45a, so that the punctiform cut-outs 45b expose the first electrical contact layer 41b on one side in the photovoltaic element B. Local stepped trenches 45a, 45b are thus provided in the region of the first cut-outs 45b in the trench.

Thereafter, an insulator 46, which is a paint, is provided in the aforementioned regions of the punctiform cut-outs 45b on both sides, beyond the edge of each trench 45a and beyond the cut-out 45b. The insulator is provided laterally over the flanks of the trenches up to the surface 43a, 43b of the second electrical contact layer 43, and on this layer (FIG. 4e): cross-section; FIG. 4i): top view). The paint Dupli-Color Aerosol Art from Motip Dupli GmbH in the hue RAL 9005 is used as the insulator 46 and can be sprayed on at a thickness of 8 μm. The insulator can be sprayed on using a metal mask having a corresponding geometry. The metal mask has punctiform openings measuring approximately 1.5 millimeters in diameter. The openings recur at regular intervals in accordance with the distances of the punctiform cut-outs 45b from each other on the substrate. By using the mask, an insulator geometry in accordance with FIG. 4e) and FIG. 4i) can be achieved. As a result of the orientation of the mask, one of the two sides, which in the present example is the side comprising the surface 43a of the second electrical contact layer 43, can be covered less laterally by way of lateral extension, by the insulator point 46, which is a non-conductive material, than the opposing side comprising the surface 43b. The surface 43a (on the left of the figure) is covered by way of a lateral extension of approximately 500 μm, by the insulator. The lateral extension of the surface 43b (on the right in the figure) comprising the insulator, in contrast, is approximately 800 μm. A top view of FIG. 4e) is provided in FIG. 4i) for a cut-out.

The application of the insulator 46 and the selection of the mask are such that all cut-outs 45b and the surface regions 43a and 43b of the second electrical contact layer are covered in a punctiform manner by the insulator 46 along all trenches 45a. Contrary to the first three exemplary embodiments, no stripe-shaped application of the insulator is provided in the fourth exemplary embodiment. The insulator 46 is rather provided in accordance with the cut-outs in punctiform manner so as to fill in the cut-outs 45b, and it is provided on the surface of the second electrical contact layer 43a, 43b. The energy efficiency of the module is increased by enlarging the surface area thereof.

The insulator 46 is removed locally and in a punctiform manner by the structuring P3. Here, a smaller punctiform cut-out 47 is created in the former cut-out 45a, 45b. P3 is provided in the region of P2. As a result of P3, the surface of the first electrical contact layer is exposed and, in the present case, the substrate is also exposed: see FIG. 4f). P3 must not expose the second electrical contact layer or the semiconductor. Each cut-out 47 is surrounded by the insulator 46a, 46b, whereby thereafter electric short circuits are prevented. The surface 41c of the first electrical contact layer of an element B is exposed.

P3 is carried out by means of selective laser ablation, selecting an Nd:YVO₄ laser from Rofin, of the RSY 20E SHG type. The output power of the laser here is 8.1 mW, at a pulse repetition frequency of 0.16 kHz, and the wavelength is 532 nm. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the substrate side, through the transparent substrate, to the layer to be ablated. The intensity distribution of the focused beam is substantially Gaussian, wherein each pulse produces a circular ablation having a diameter of approximately 100 μm, which is thus smaller than P2. The laser creates a punctiform local stepped trench 47 inside the former, and now filled-in, first trenches 45a and the cut-outs 45b (FIG. 4f)). This once again exposes the surface of the first electrical contact layer 41c and the surface of the substrate 44 directly adjacent to one another in the manner of a shoulder or step (see FIG. 4f)). Only because of the cross-sectional view, the insulator behind the sheet plane is apparent in the bolded area in FIG. 4f). The perpendicularly extending edge regions 46a and 46b of the insulator in FIG. 4f) remaining after the structuring P3 are in fact, of course, closed in a circular shape and thereafter prevent short circuiting of the photovoltaic elements A and B. The relationship is clarified in FIG. 4j), which is a top view of FIG. 4f).

P3 is repeated as many times as the number of punctiform cut-outs 45b that were created. The layers 41, 42 and 43 are divided into a plurality of stripe-shaped, parallel photovoltaic elements, separated by the stripe-shaped trenches 45a and separated by the punctiform cut-outs 45b. Within the meaning of the invention, stepped trenches are also present locally in the cut-outs in exemplary embodiment 4.

In the final step, the second punctiform cut-outs 47 are again filled locally with contact material 48, so that contact is established between the surface of the second electrical contact layer of a photovoltaic element A and the first electrical contact layer of an adjoining element B. The exposed surface 41c of the first electrical contact layer of element B in the second cut-out 47 is thus electrically contacted only with the surface of the second electrical contact layer 43a of the photovoltaic element A (FIG. 4g)). Advantageously, this requires less contact material for filling the stepped trench, and the surface area for energy conversion is enlarged as compared to the first exemplary embodiments 1 to 3.

The electrical contact between the surface of the second electrical contact layer 43a and the surface of the first electrical contact layer 41c, and hence the series connection of adjoining photovoltaic elements A and B, and so forth, are thus completed on all cut-outs 47. The distances and sizes of the cut-outs 47 of each trench are dimensioned such that it is possible to discharge the energy that is generated.

Silver having a thickness of approximately 200 nm can be employed as the contact material. The cut-outs 47 are likewise filled in using mask techniques. To this end, a mask that is similar to the mask used to apply the insulator is employed. This mask has openings in the same locations as the mask that was employed to apply the insulator, however the openings have a different geometry. These are stripe-shaped openings having a width of approximately 0.5 mm and a length of approximately 2 millimeters, see FIG. 4a, (on the left in the figure) and FIG. 4k). The shorter side is disposed parallel to the trench 45a. The silver is applied to the substrate by way of the mask using a thermal evaporation process. The cut-outs 47 are filled with contact material 48 so that only the surface of the second electrical contact-layer 43a of element A, and not the surface of the second electrical contact layer 43b of the photovoltaic element B, is contacted with the exposed surface of the first electrical contact layer 41c in the holes 47. This is achieved by a slightly offset orientation of the mask, by approximately 0.5 mm as compared to the orientation of the mask when applying the insulator, and by the modified geometry of the openings of the mask. FIG. 4k), as a top view of FIG. 4g), illustrates the relationship for a single cut-out 47 on a trench 45a.

Filling the second punctiform cut-outs 47 with contact material 48 is repeated along all points (see FIG. 4a)) until all photovoltaic elements inside the module are thus connected in series to one another.

### Fifth Exemplary Embodiment

A solar cell, which is produced on a glass substrate measuring 10×10 cm² and having a thickness of 1.1 mm, is used as the basis for the exemplary embodiment. The thickness of the microcrystalline p-i-n layer stack 52 (active semiconductor layer, FIG. 5) here is approximately 1300 nanometers in total. The microcrystalline layer stack is provided on a first electrical contact layer 51 that comprises zinc oxide, which has been textured by way of a wet-chemical process, and has a thickness of approximately 800 nanometers. A layer system comprising approximately 80 nm zinc oxide in combination with a 200 nm thick silver layer is used as the second electrical contact layer 53. First the zinc oxide layer, followed by the silver layer, are provided on the silicon layer stack on the side of the second electrical contact layer.

By way of the first structuring P1 (FIG. 5c)), material is removed from the second electrical contact layer 53 and from the active semiconductor layers 52, as well as from the first electrical contact layer 51, by way of laser ablation, whereby the surface of the substrate 54 is exposed in the trenches 55a over the length of the photovoltaic elements. P1 is carried out consecutively for all photovoltaic elements A, B, C, and so forth, that are to be created. The laser is guided for this purpose over the surface of the substrate using a relative movement. The distance and output power are adjusted so that material of the layers 51, 52 and 52 is removed. The laser that is employed is an Nd:YVO₄ laser from Rofin, of the RSY 20E THG type. The wavelength of the laser is 355 nm. This wavelength is specific to the ablation of the materials of layers 51 to 53. An average output power of 390 mW at a pulse repetition rate of 15 kHz is selected. The velocity of the relative movement between the laser beam and substrate is approximately 580 mm/s. The duration of the individual pulses is approximately 13 ns. The laser radiation is focused on the layer side of the substrate using a focusing unit that has a focal distance of 100 mm. The beam is conducted from the substrate side to the layers to be ablated, through the transparent substrate. The intensity distribution of the focused beam is substantially Gaussian, wherein each pulse produces a circular ablation having a diameter of approximately 53 μm.

A plurality of trenches 55a, such as 8 to 12, for example, for the photovoltaic elements A, B, C, and so forth, are thus present on the substrate 54 parallel to one another, see the vertical lines in the module on the right (top view), in FIG. 5a). Following P1, a trench 55a is respectively located between two directly adjoining photovoltaic elements A, B or B, C, and so forth. P1 is carried out using computer-assisted control. The structuring P1 is repeated a number of times equal to the number of photovoltaic elements A, B, C, and so forth, that are to be created.

By way of a second structuring P2, the layers 52 and 53 are ablated in certain regions over the length of the photovoltaic elements. In the present example, these are provided in a punctiform manner and on one side of each trench 55a along the dotted line P4 up to the surface of the first electrical contact layer (FIG. 5d)). Only because of the cross-sectional view, the material of layer 52 and of layer 53 is apparent in FIG. 5d) behind the sheet plane in the region of the punctiform cut-out 55b. The punctiform cut-outs 55b have a distance of approximately 1 millimeter to 5 millimeters from one another in the direction of the stripe-shaped trench 55a, which is to say over the length of a photovoltaic element. It is possible, however, to select different distances and sizes. An Nd:YVO₄ laser from Rofin, of the RSY 20E SHG type, is employed as the laser for ablating the material from layers 52 and 53 in the region 55b. The wavelength of the laser is 532 nanometers and is specific to the ablation of the layers 52, 53. An average output power of 48 mW at a pulse repetition rate of 0.16 kHz is selected. The velocity of the relative movement between the laser beam and substrate is approximately 800 mm/s. The duration of the individual pulses is approximately 13 ns. The laser radiation is focused on the layer side of the substrate using a focusing unit that has a focal distance of 300 mm. The beam is conducted from the substrate side to the layers to be ablated, through the transparent substrate. The intensity distribution of the focused beam is approximately Gaussian. Each pulse produces a circular ablation having a diameter of approximately 200 μm. The diameter of the circular ablation was produced using a divergence lens and was adjusted prior to focusing the laser beam.

Subsequent to the two structurings P1, P2, the photovoltaic elements A, B, C, and so forth, are separated from one another down to the substrate 54. As a result, the stripe-shaped, parallel photovoltaic elements A, B, C, and so forth, are present on the substrate 54, electrically and spatially insulated from one another by the trenches 55a over the length of the photovoltaic elements. A plurality of first trenches 55a, each having punctiform cut-outs 55b on one side, are thus created for separating the photovoltaic elements A, B, C, and so forth. In the first punctiform cut-outs 55b in the trenches, the surfaces of the first electrical contact layer 51b and of the substrate 54 are present directly adjacent to one another, so that a shoulder in the form of a local stepped trench 55a, 55b according to the invention is created. Because this structuring P2 involves a plurality of merely punctiform structurings along the length of the trenches 55a of the layer structure, the semi-conducting layers 52 and the second electrical contact layer 53 are preserved over a large region along the stripe-shaped trenches 55a. Advantageously, this increases the surface area that is available for generating energy.

The punctiform cut-outs 55b in the trenches are provided on one side, because only the surface 51b of the first contact layer, to the right of the trench 55a, which is to say of element B, is exposed in the punctiform cut-outs 55b. P2 is repeated until the layers 51, 52 and 53 for a plurality of stripe-shaped, parallel photovoltaic elements A, B, C, in the trenches 55a have been separated and can be insulated by punctiform cut-outs 55b. The cut-outs have a diameter of approximately 200 μm. In the region of the first cut-outs 55b, according to the invention, locally disposed stepped trenches 55a and 55b are created. In this respect, this exemplary embodiment is consistent with the fourth exemplary embodiment of FIG. 4.

The insulator 56, however, is designed as an electrically non-conductive and diffusely reflecting layer and is provided over the entire surface area until all local stepped trenches 55a, 55b and the surface 53 of the second electrical contact layer have been covered thereby. This is carried out by way of screen printing. This step is advantageously carried out more quickly, as compared with the other exemplary embodiments. The insulator that is selected is advantageously a “white reflector”, for example white color 3070 from Marabu. The layer thickness is approximately 20 μm.

The insulator 56 is then selectively removed, or structured, in a punctiform manner in the former stepped trenches 55a, 55b by way of the structuring P3a. The resulting punctiform stepped trench 57a is positioned by P3a so as to be located between the respective right and left outer edges of the former stepped trench 55b, 55a. Electric short circuiting is thus prevented. P3a is carried out so as to expose the surface of the first electrical contact layer 51c of element B. The removal is carried out by means of selective laser ablation, selecting an Nd:YVO₄ laser from Rofin, of the RSY 20E SHG type. The output power of the laser is 8.1 mW, at a pulse repetition frequency of 0.16 kHz, and the wavelength is 532 nm. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the substrate side, through the transparent substrate, to the layer to be ablated. The intensity distribution of the focused beam is substantially Gaussian, wherein each pulse produces a circular ablation having a diameter of approximately 100 μm. The laser creates a second punctiform stepped trench 57a inside the former, and now filled-in, first trenches 55a, 55b, see FIG. 5f). This once again exposes the surface of the first electrical contact layer 51c and the surface of the substrate 54a directly adjacent to one another in the manner of a local stepped trench 57a. The insulator can be seen in the region 57a only because of the sectional view. P3a is again repeated along all former punctiform openings 55b over the length of all the photovoltaic elements. To this end, local stepped trenches 57a that are laterally slightly offset with respect to the stepped trenches 55a, 55b are produced, which are surrounded by the insulator for electrically insulating the cells (see FIG. 5f), see also FIGS. 4j) and 5i)). The annular regions 56a, 56b of the insulator remaining after P3a prevent short circuiting of the two photovoltaic elements A and B. P3a is repeated for all former punctiform stepped trenches 55a, 55b.

As differs from the other exemplary embodiments, further punctiform structurings P3b follow along the dotted lines. As a result, the second electrical contact layer 53 can be designed to have lower conductivity, and thus also lower optical losses. It is thus possible to design the insulator as a diffuse reflector, which increases the energy yield. In the region of the cell stripes A, B, C, and so forth, P3b exposes the surface of the second electrical contact layer 53 by further punctiform cut-outs 57b in the insulator 56. The punctiform cut-outs are provided at a distance from one another that is adapted to the electric resistance of the layer 53, for example at a distance of 1 millimeter to 3 millimeters. The insulator that is provided behind the sheet plane is apparent in the structurings P3b only because of the cross-sectional view.

The removal is carried out by means of selective laser ablation, selecting an Nd:YVO₄ laser from Rofin, of the RSY 20E SHG type. The output power of the laser here is 8.1 mW, at a pulse repetition frequency of 0.16 kHz, and the wavelength is 532 nm. The velocity of the relative movement between the laser beam and substrate is 800 mm/s. The duration of the individual pulses is approximately 13 ns. The laser radiation is focused on the layer side of the substrate using a focusing unit that has a focal distance of 300 mm. To this end, the beam is conducted from the layer side to the layer to be ablated. The intensity distribution of the focused beam is substantially Gaussian, wherein each pulse produces a circular ablation having a diameter of approximately 100 μm. A top view of FIG. 5f) is provided in FIG. 5i).

Thereafter, the second punctiform cut-outs 57a and 57b are filled with contact material 58 over the entire surface area, whereby the entire surface of the insulator 56 is covered by contact material 58. The exposed surface 51c of the first electrical contact layer of the photovoltaic element B is thus electrically contacted in the cut-outs 57a with the surface of the second electrical contact layer 53 of the photovoltaic elements A and B (FIG. 5g)). This application of the contact material 58 is advantageously carried out quickly, using inexpensive material such as aluminum or silver, because there are no requirements in terms of reflection, given the white reflector, which serves as the insulator. As an additional effect, this reflection of the insulator is even improved by selecting silver or aluminum for the contact.

P4 is carried out for the electric insulation along the dotted line over the length of all photovoltaic elements. P4 is created by way of laser ablation. An Nd:YVO₄ laser from Rofin, of the RSY 20E SHG type is selected. The output power of the laser is 8.1 mW, at a pulse repetition frequency of 0.16 kHz, and the wavelength is 532 nm. The velocity of the relative movement between the laser beam and substrate is 800 mm/s. The duration of the individual pulses is approximately 13 ns. The laser radiation is focused on the layer side using a focusing unit that has a focal distance of 300 mm. The beam is conducted from the layer side (back contact) to the layer 56 to be ablated. The intensity distribution of the focused beam is substantially Gaussian, wherein each pulse produces a circular ablation having a diameter of approximately 100 μm.

The electrical contact between the surface of the second electrical contact layer 53a and the surface of the first electrical contact layer 51c, and hence the series connection of the two photovoltaic elements A and B, are thus completed (FIG. 5h)). In addition, the insulation is produced by creating the stripe-shaped trench 58a over the length of the photovoltaic elements. A top view of this is shown in FIG. 5j). Short circuiting is thus prevented in element B.

The contact material 58 that is employed can be silver or aluminum. The second punctiform cut-outs 57a are filled in using sputtering methods. Subsequent to P4, only the surface of the second electrical contact layer 53a of the photovoltaic element A, and not the surface of the second electrical contact layer 53b of the photovoltaic element B, is contacted in the punctiform cut-outs 57a with the exposed surface of the first electrical contact layer 51c. This process is repeated for all trenches and photovoltaic elements.

The method steps described in the exemplary embodiments shall not be construed to be of a limiting nature. The lateral dimensions of the stepped trenches, and the sizes and distances of the insulator and contact stripes or points, as well as the layer materials of the layers of the photovoltaic elements as such, and the composition of the insulator, as well as the contact material, shall not result in any restriction of the invention, but rather should be broadly interpreted. Notably, a suitable ink, such as conventional ink jet printer ink, may be used as the insulator, instead of the aforementioned insulator paints. Moreover, it is easily possible to provide parts of the module with a stripe-shaped insulator (FIGS. 1 to 3) and to provide other parts of the module with an insulator in a punctiform manner. In this respect, the methods according to the exemplary embodiments can also be employed simultaneously.

The method steps of exemplary embodiments 1 to 5 shown in the cross-sectional and top views of the two photovoltaic elements A and B illustrate series connection of these two elements A and B. These steps are carried out accordingly for the remaining photovoltaic elements in the module.

In addition, further exemplary embodiments 6 to 10 are provided, in which in FIGS. 1f), 2f), 3f), 4f) and 5f) the respective insulator is structured so that only the surface of the first electrical contact layer 1c, 21c, 31c, 41c and 51c, and not the respective substrate surface adjoining to the left thereof, is exposed.

In accordance with the exemplary embodiments 1 to 10, additional exemplary embodiments 11 to 20 are provided, in which the insulator and/or the contact material are applied in computer-controlled manner using an ink jet printer.

In addition, further exemplary embodiments are provided, which implement combinations, as in Table 1. It is easily conceivable to provide a layer over the entire surface area, instead of the fillings provided in a stripe-shaped manner over the length of the photovoltaic elements, and to then structure this layer, as in exemplary embodiment 5.

| Step in: | Geometry or Shape | | | | | | | |
|---|---|---|---|---|---|---|---|---|
| Claim 1d): Exposed | Stripes¹ | | | | | | | |
| substrate surface of | | | | | | | | |
| each stepped trench | | | | | | | | |
| in the form of: | | | | | | | | |
| Claim 1d): Exposed | Stripes¹ | | | | Regions² | | | |
| surface of the 1^{st} | | | | | | | | |
| electrical contact | | | | | | | | |
| layer of each | | | | | | | | |
| stepped trench in | | | | | | | | |
| the form of: | | | | | | | | |
| Claim 1e): | Stripes¹ | Regions² | Full-surface-area | | Regions² | Stripes¹ | Full-surface-area | |
| Application of the | | | | | (FIG. 4) | | (FIG. 5) | |
| insulator in the form | | | | | | | | |
| of: | | | | | | | | |
| Claim 1f): Removing | a) Stripes¹ | Regions² | In the | Next to | Regions² | a) Regions² | In the | Next to the |
| insulator locally and | (FIGS. 1-3) | | stepped | the | (FIG. 4) | b) Stripes^{1,4} | stepped | stepped |
| exposing the first | b) Regions² | | trench: | stepped | | | trench: | trench: |
| electrical contact | | | a) | trench: | | | a) | a) |
| layer in the form of: | | | Regions² | a) | | | Regions² | Regions² |
| | | | b) Stripes¹ | Regions² | | | (see FIG. | (see FIG. |
| | | | | b) | | | 5) | 5) |
| | | | | Stripes¹ | | | b) | b) Stripes |
| | | | | | | | Stripes^{1,4} | |
| Claim 1g): Series | a) Stripes¹ | Regions² | a) | a) | Regions² | a) Regions^{2,4} | a) | a) |
| connection of the | (see FIGS. 1-3) | | Regions² | Regions² | (FIG. 4) | b) Stripes¹ | Regions^{2,4} | Regions² |
| first and second | b) Regions² | | b) Stripes¹ | b) | | | b) Stripes¹ | b) Stripes¹ |
| contact layers of | | | | Stripes¹ | | | c) Full- | c) Full- |
| adjoining | | | | c) Full- | | | surface- | surface- |
| photovoltaic | | | | surface- | | | area | area³ |
| elements as or in: | | | | area³ | | | | |

¹“Striped shape” denotes a geometry over the length of a photovoltaic element, see, for example, FIGS. 1a) to FIG. 3a)
²“Region” denotes a geometry over only a smaller region of the surface of a photovoltaic element, for example a region in the shape of a dot, see for example FIGS. 4 H-k) or FIG. 5 i). The regions are provided in a perforation-like manner along the stripes.
³In the case of a contact layer covering the entire surface area on the second contact layer of the module, in the end, this full-surface-area contact layer is also structured (see FIG. 5).
⁴In this case, in step 1g) it is only possible to apply contact material in regions

1. A method for generating and for connecting in series photovoltaic elements on a substrate, comprising the following steps:
a) providing a first electrical contact layer on the substrate;
b) providing active semiconductor layers on top of one another on the first electrical contact layer;
c) providing a second electrical contact layer on the active semiconductor layers on the side of the semiconductor layers located opposite of the first contact layer;
d) creating a plurality of parallel stepped trenches so as to form and separate a plurality of photovoltaic elements (A, B, C . . . ), wherein the surface of the substrate and the surface of the first contact layer next to one another are exposed in the respective stepped trenches;
e) providing insulator material in the stepped trenches;
f) locally removing the insulator material, whereby the surface of the first electrical contact layer of a photovoltaic element (B) in the stepped trenches is exposed; and
g) providing contact material from the surface of the second electrical contact layer of a photovoltaic element (A) up to the surface of the first electrical contact layer of the adjoining photovoltaic element (B) from which the insulator material has been removed.

2. A method according to claim 1, wherein, in step d), in the stepped trenches, the surface of the substrate over the length of the photovoltaic element and the surface of the first electrical contact layer next to the exposed substrate surface are likewise exposed over the length of the photovoltaic elements, or in regions.

3. A method according to claim 1, wherein the insulator material in step e) is provided in the stepped trenches over the length of the photovoltaic elements, or locally on the exposed regions of the first electric contact layer.

4. A method according to claim 1, wherein the insulator material in step e) is provided over the entire surface area of the surface of the layer structure.

5. A method according to claim 1, wherein the insulator material in step f) is removed in the stepped trenches over the length of the photovoltaic elements, or locally in regions.

6. A method according to claim 4, wherein insulator material is removed over the length of the photovoltaic elements, or in regions, adjacent to the stepped trenches.

7. A method according to claim 1, wherein the contact material in step g) is provided in the stepped trenches over the length of the photovoltaic elements, or on the exposed regions of the first electrical contact layer.

8. A method according to claim 1, wherein the contact material in step g) is provided over the entire surface area of the surface of the layer structure.

9. The method according to claim 8, wherein parallel adjacent to the stepped trenches, the contact material is removed over the length of the photovoltaic elements so as to expose the surface of the insulator.

10. A method according to claim 1, wherein a layer having lower conductivity than the first electrical contact layer is selected as the second electrical contact layer.

11. A method according to claim 1, wherein a white reflector is selected as the insulator.

12. A method according to claim 1, comprising providing stripe-shaped or punctiform regions.

13. A method according to claim 1, comprising an arrangement of the insulated regions and the contacted regions with respect to one another so that short circuits are prevented in the photovoltaic elements.

14. A solar module, comprising a plurality of parallel photovoltaic elements between which insulator material is provided in stepped trenches, and in which contact material, which brings a second electrical contact layer of a photovoltaic element in contact with the first electrical contact layer of an adjoining element, is provided in the insulator material.

15. A solar module according to the preceding claim 14, wherein the insulator material and/or contact material are present in a stripe-shaped manner over the length of the photovoltaic element or in regions, preferably in punctiform manner.

16. A solar module according to claim 14, wherein the contact material is provided over the entire surface area of the second electric contact layer.
